(19) United States
(12) Patent Application Publication
(10) Pub. No.: US 2014/0326957 A1
(43) Pub. Date: Nov. 6, 2014

(54) ORGANIC LIGHT EMITTING DISPLAY DEVICE AND METHOD OF MANUFACTURING THE SAME

(71) Applicant: Samsung Display Co., Ltd., Yongin-city (KR)

(72) Inventor: Young-Hee Lee, Yongin-city (KR)

(73) Assignee: Samsung Display Co., Ltd., Yongin-city (KR)

(21) Appl. No.: 13/971,539

(22) Filed: Aug. 20, 2013

(30) Foreign Application Priority Data
May 2, 2013 (KR) 10-2013-0049450

(51) Int. Cl. H01L 27/32; H01L 51/50

(52) U.S. Cl. CPC H01L 27/3206; H01L 51/504
USPC 257/40; 438/34

(57) ABSTRACT

In an aspect, an organic light emitting display device includes a first electrode, a second electrode on the first electrode, an organic light emitting layer on the first electrode, a hole transfer layer between the first electrode and the organic light emitting layer, a hole injection layer between the first electrode and the hole transfer layer and a functional layer between the hole transfer layer and the hole injection layer, and including a blue light emitting material is provided.

### INCORPORATION BY REFERENCE TO ANY PRIORITY APPLICATIONS

Any and all priority claims identified in the Application Data Sheet, or any correction thereto, are hereby incorporated by reference under 37 CFR 1.57. For example, this application claims the benefit of Korean Patent Application No. 10-2013-0049450, filed on May 2, 2013 in the Korean Intellectual Property Office (KIPO), the disclosure of which is herein incorporated by reference in its entirety.

### BACKGROUND

1. Field

This disclosure relates to an organic light emitting display device and a method of manufacturing the same. For example, the present disclosure relates to an organic light emitting display device having improved luminance, luminous efficiency and life time and a method of forming the organic light emitting display device.

2. Description of the Related Technology

An organic light emitting display device displays an image by using an organic light emitting diode (OLED) which emits a light. Since an organic light emitting display device does not need a backlight, size, thickness, weight and power consumption may be decreased in comparison to other display devices. Furthermore, an organic light emitting display device may improve color reproduction characteristics and reaction speed.

Generally, an organic light emitting display device includes an organic light emitting diode including an organic light emitting layer interposed between two electrodes. Furthermore, various layers such as hole injection layer, and an electron transfer layer are formed to improve luminance and to decrease power consumption.

Typically, lifetime of a blue diode is shorter than those of a red diode and a green diode. In order to increase the lifetime of a blue diode, materials of a blue diode are under investigation.

### SUMMARY

Some embodiments provide an organic light emitting display device capable of improved a luminance, a luminous efficiency and a lifetime of organic light emitting display device.

Some embodiments provide a method of manufacturing an organic light emitting display device capable of improved a luminance, a luminous efficiency and a life time of organic light emitting display device.

Some embodiments provide an organic light emitting display device may include a first electrode, a second electrode disposed on the first electrode, an organic light emitting layer disposed on the first electrode, a hole transfer layer disposed between the first electrode and the organic light emitting layer, a hole injection layer disposed between the first electrode and the hole transfer layer and a functional layer disposed between the hole transfer layer and the hole injection layer, and comprising a blue light emitting material.

In some embodiments, the organic light emitting display device may further include an interlayer disposed between the hole transfer layer and the hole injection layer.

In some embodiments, the organic light emitting display device may further include an electron injection layer disposed between the organic light emitting layer and the second electrode.

In some embodiments, the organic light emitting display device may further include an electron transfer layer disposed between the electron injection layer and the organic light emitting layer.

In some embodiments, the organic light emitting display device may further include an optical control layer disposed between the organic light emitting layer and the functional layer.

In some embodiments, the organic light emitting layer may include a first organic light emitting layer, a second organic light emitting layer and a third organic light emitting layer, and the first emitting layer emit blue visible ray, the second emitting layer emit red visible ray and the third emitting layer emit green visible ray.

In some embodiments, the first organic light emitting layer may be disposed in a first sub-pixel area, the second organic light emitting layer may be disposed in a second sub-pixel area, and the third organic light emitting layer may be disposed in a third sub-pixel area.

In some embodiments, the blue light emitting material may include Alq3, 4,4′-N,N′-dicabazolebiphenyl (CBP), poly(n-vinylcabazole), 9,10-di(naphthalene-2-yl)anthracene (ADN), Tris(4-carbazoyl-9-ylphenyl)amine (TCTA), 1,3,5-tris(Nphenylbenzimidazole-2-yl)benzene (TPBI), 3-tert-butyl-9,10-di(naphth-2-yl) anthracene (TBADN), distyrylarylene (DSA), anthracene dinaphthalene, anthracene dibiphenyl, anthracene naphthalene biphenyl or anthracene diphenyl.

In some embodiments, the functional layer may include oxadiazole dimmer dye (Bis-DAPDXP), spiro-4,4′-bis(2,2′diphenylvinil)-1,1′-biphenyl(spiro-DPVBi), 2,2′,7,7′-tetrakis(biphenyl-4-yl)-9,9′-spirobifluorene (spiro-6P), triarylamine compound, bis(styryl)amine, 4,4′-bis(9-ethyl-3-carbazovinylene)-1,1′-biphenyl(BCzVBi), perylene, 2,5,8,11-tetra-tert-butylperylene (TPBe), 9H-carbazole-3,3′-(1,4-phenylene-di-2,1-ethene-diyl)bis[9-ethyl-(9C)] (BCzVB), 4,4-bis[4-(di-p-toylamino)styryl]biphenyl (DPAVBi), 4-(di-p-toylamino)-4′-[(di-p-toylamino)styryl]stillbene (DPAVB), 4,4′-bis[4-(diphenylamino)styryl]biphenyl (BDAVBi), bis(3,5-difluoro-2-(2-pyridyl)phenyl-(2-carboxypyridyl)iridium III (FIrPic) or polyfluorene polymer and polybinyl polymer.

In some embodiments, a thickness of the functional layer is about 1 Å to about 50 Å.

Some embodiments provide a method of manufacturing an organic light emitting display device. A first electrode may be formed on a base substrate. A hole injection layer may be formed. A functional layer including a blue light emitting material may be formed. A hole transfer layer may be formed. An organic light emitting layer including a first organic light emitting layer, a second organic layer and a third organic layer may be formed on the first electrode. A second electrode may be formed on the first electrode.

In some embodiments, an interlayer may be formed between the hole transfer layer and the hole injection layer.

In some embodiments, an electron injection layer may be formed between the first electrode and the second electrode.

In some embodiments, an electron transfer layer may be formed between the electron injection layer and the organic light emitting layer.

In some embodiments, an optical control layer may be formed between the organic light emitting layer and the functional layer.

In some embodiments, the functional layer may include Alq3, 4,4′-N,N′-dicabazolebiphenyl (CBP), poly(n-vinylcabazole), 9,10-di(naphthalene-2-yl)anthracene (ADN), Tris(4-carbazoyl-9-ylphenyl)amine (TCTA), 1,3,5-tris(Nphenylbenzimidazole-2-yl)benzene (TPBI), 3-tert-butyl-9,10-di(naphth-2-yl) anthracene (TBADN), distyrylarylene (DSA), anthracene dinaphthalene, anthracene dibiphenyl, anthracene naphthalene biphenyl or anthracene diphenyl.

In some embodiments, the functional layer may include oxadiazole dimmer dye (Bis-DAPDXP), spiro-4,4′-bis(2,2′diphenylvinil)-1,1′-biphenyl (spiro-DPVBi), 2,2′,7,7′-tetrakis(biphenyl-4-yl)-9,9′-spirobifluorene (spiro-6P), triarylamine compound, bis(styryl)amine, 4,4′-bis(9-ethyl-3-carbazovinylene)-1,1′-biphenyl (BCzVBi), perylene, 2,5,8,11-tetra-tert-butylperylene (TPBe), 9H-carbazole-3,3′-(1,4-phenylene-di-2,1-ethene-diyl)bis[9-ethyl-(9C)] (BCzVB), 4,4-bis[4-(di-p-toylamino)styryl]biphenyl (DPAVBi), 4-(di-p-toylamino)-4′-[(di-p-toylamino)styryl]stillbene (DPAVB), 4,4′-bis[4-(diphenylamino)styryl]biphenyl (BDAVBi), bis(3,5-difluoro-2-(2-pyridyl)phenyl-(2-carboxypyridyl)iridium III (FIrPic), polyfluorene polymer or polybinyl polymer.

In some embodiments, the functional layer may include blue light emitting material. Thus, lifetime and luminous efficiency of an organic light emitting diode may be improved, and roll-off may be improved in red diode including phosphors.

### BRIEF DESCRIPTION OF THE DRAWINGS

The above and other features and advantages of the present disclosure will become more apparent by describing in detailed exemplary embodiments thereof with reference to the accompanying drawings, in which:

FIG. 1 is cross-sectional view illustrating an organic light emitting display device according to an exemplary embodiment of the present invention;

FIG. 2 is a cross-sectional view illustrating an organic light emitting display device according to an exemplary embodiment of the present invention;

FIGS. 3 to 10 are cross-sectional views illustrating a method of manufacturing an organic light emitting display device illustrated in FIG. 2;

FIG. 11 is a graph illustrating life time of an organic light emitting display device according to an exemplary embodiment of the present invention with compared to general technology; and

FIG. 12 is a graph illustrating a progressive driving voltage of an organic light emitting display device according to an exemplary embodiment of the present invention with compared to general technology.

### DETAILED DESCRIPTION

Various example embodiments will be described more fully hereinafter with reference to the accompanying drawings, in which some example embodiments are shown. The present disclosure may, however, be embodied in many different forms and should not be construed as limited to the example embodiments set forth herein. In the drawings, the sizes and relative sizes of layers and regions may be exaggerated for clarity. Like numerals refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present invention will be explained in detail with reference to the accompanying drawings.

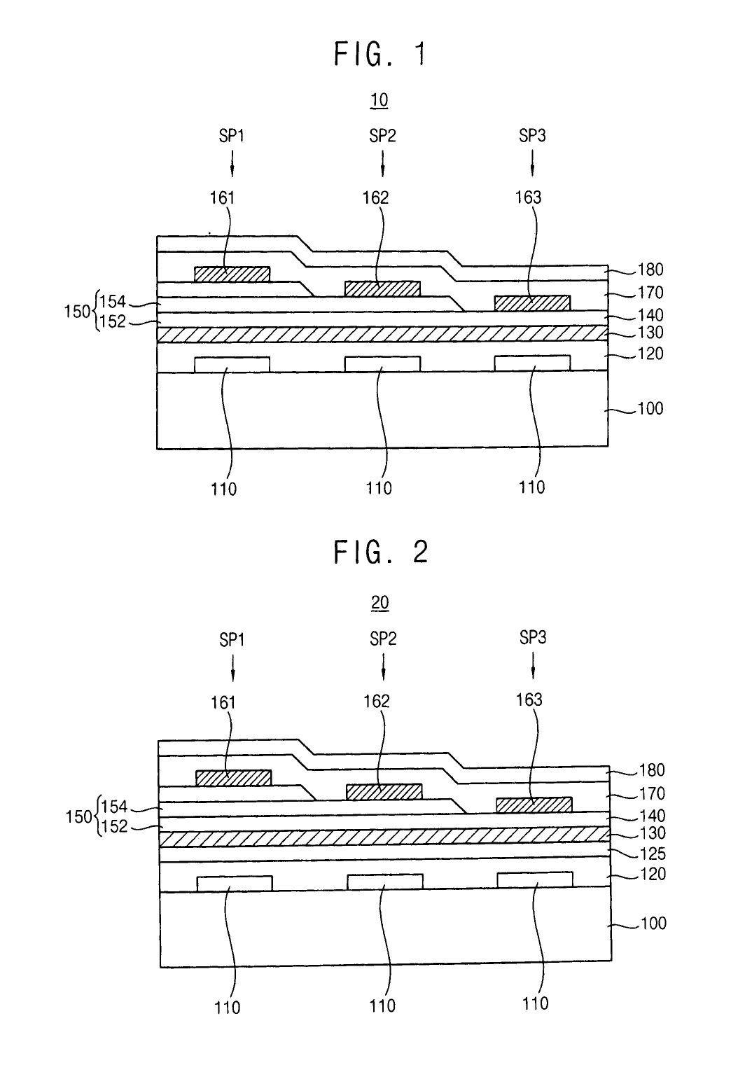

FIG. 1 is a cross-sectional view illustrating an organic light emitting display device according to an exemplary embodiment of the present invention.

Referring to FIG. 1, an organic light emitting display device 10 includes a base substrate 100, a first electrode 110, a hole injection layer 120, a functional layer 130, a hole transfer layer 140, an optical control layer 150, an electron transfer layer 170 and a second electrode 180.

In some embodiments, the base substrate 100 includes a transparent insulation substrate. For example, the base substrate may include a glass substrate, a quartz substrate, or a transparent resin substrate, or etc. The transparent resin substrate may include polyamide resin, acryl resin, polyacrylate resin, polycarbonate resin, polyether resin, polyethylene terephthalate resin, or sulfonic acid resin, or etc.

In some embodiments, the first electrode 110 may be disposed on the base substrate 100. In some embodiments, the first electrode 110 may be a reflection electrode or a transmission electrode depending on an emitting type of the organic light emitting display device. When a first electrode 110 is a reflection electrode, the first electrode may include indium zinc oxide (IZO), indium tin oxide (ITO), gallium zinc oxide (GZO), zinc oxide (ZnOx), gallium oxide (GaOx), tin oxide (TiOx) or indium oxide (InOx), or etc. When a first electrode 110 is a transmission electrode, the first electrode may include aluminum (Al), silver (Ag), gold (Au), platinum (Pt), chromium (Cr), tungsten (W), molybdenum (Mo), titanium (Ti) or palladium (Pd), or etc.

When the organic light emitting display device have an active driving type, a switching structure may be disposed between the base substrate 100 and the first electrode 110. For example, the switching structure may include a switching diode such as a transistor and a plurality of insulation layers, and may be electrically connected to the first electrode 110.

In some embodiments, the hole injection layer 120 may be disposed on the first electrode 110. In some embodiments, the hole injection layer 120 may include phthalocyanine compound such as copper phthalocyanine, starburst amine compound such as TCTA, m-MTDATA, m-MTDAPB, or etc. In some embodiments, the hole injection layer 120 serves to easily move efficiently positive holes provided from the first electrode 110 to improve electrical characteristics.

In some embodiments, the functional layer 130 may be disposed between the hole injection layer 120 and the hole transfer layer 140. In some embodiments, the functional layer 130 may include one blue light emitting material, or combination of a blue host material and a blue dopant material. For example, the functional layer may include Alq3, (4,4′-N,N′-dicabazolebiphenyl) (CBP), poly(n-vinylcabazole), (9,10-di(naphthalene-2-yl)anthracene) (ADN), Tris(4-carbazoyl-9-ylphenyl)amine (TCTA), (1,3,5-tris(Nphenylbenzimidazole-2-yl)benzene) (TPBI), (3-tert-butyl-9,10-di(naphth-2-yl)anthracene) (TBADN), (distyrylarylene) (DSA), anthracene dinaphthalene, anthracene dibiphenyl, anthracene naphthalene biphenyl or anthracene diphenyl. In some embodiments, the functional layer 130 may include oxadiazole dimmer dye (Bis-DAPDXP), spiro-4,4′-bis(2,2′diphenylvinil)-1,1′-biphenyl (spiro-DPVBi), 2,2′,7,7′-tetrakis(biphenyl-4-yl)-9,9′-spirobifluorene (spiro-6P), triarylamine compound, bis(styryl)amine, 4,4′-bis(9-ethyl-3-carbazovinylene)-1,1′-biphenyl (BCzVBi), perylene, 2,5,8,11-tetra-tert-butylperylene (TPBe), 9H-carbazole-3,3′-(1,4-phenylene-di-2,1-ethene-diyl)bis[9-ethyl-(9C)] (BCzVB), 4,4-bis[4-(di-p-toylamino)styryl]biphenyl (DPAVBi), 4-(di-p-toylamino)-4′-[(di-p-toylamino)styryl]stillbene (DPAVB), 4,4′-bis[4-(diphenylamino)styryl]biphenyl (BDAVBi), bis(3,5-difluoro-2-(2-pyridyl)phenyl-(2-carboxypyridyl)iridium III (FIrPic), polyfluorene polymer or polybinyl polymer.

In some embodiments, a thickness of the functional layer 130 may be about 1 Å to about 50 Å. In some embodiments, a thickness of the functional layer 130 may be about 1 Å to about 10 Å.

In some embodiments, the hole transfer layer 140 may be disposed on the functional layer 130. In some embodiments, the hole transfer layer 140 may include N,N′-bis(3-metylphenyl)-N,N′-diphenyl-[1,1-biphenyl]-4,4′-diamine (TPC), N,N′-di(naphthalene-1-yl)-N or N′-diphenyl benzidine (α-NPD). In some embodiments, the hole transfer layer 140 serves to easily move positive holes from the hole injection layer 120 to an organic light emitting layer 160.

In some embodiments, the optical control layer 150 may be disposed on the hole transfer layer 140. In some embodiments, the optical control layer 150 includes a first optical path control layer 152 and a second optical path control layer 154. In some embodiments, the optical control layer 150 serves as a layer for resonance from light of the organic light emitting layer 160. In some embodiments, the optical control layer 150 may be formed from hole transfer materials, and may have different thicknesses to have an resonance thickness corresponding to sub-pixels. In some embodiments, a thickness of the hole transfer layer 140 for the blue sub-pixel may be adjusted to that the optical control layer 150 may be omitted for the blue sub-pixel. In some embodiments, the second optical path control layer 154 may be disposed on the first optical path control layer 152. In some embodiments, the first optical path control layer 152 and the second optical path control layer 154 may include alloy or metals, which have high reflectance, such as Ag, or Mg, and a material such as SiN, SiO, TiO₂, Ta₂O₅, ITO, IZO, or etc. for controlling optical path

In some embodiments, the organic light emitting layer 160 may be disposed on the hole transfer layer 140 and the optical control layer 150. In some embodiments, the organic light emitting layer 160 includes a first organic light emitting layer 161, a second organic light emitting layer 162 and a third organic light emitting layer 163. In some embodiments, the first organic light emitting layer 161 may emit red visible rays, the second organic light emitting layer 162 may emit green visible rays, and the third organic light emitting layer 163 may emit blue visible rays.

In some embodiments, the first organic light emitting layer 161 is disposed in a first sub-pixel area SP1. In some embodiments, the first organic light emitting layer 161 may emit red visible rays and may include tetraphenylnaphthacene (Rubrene), tris(1-phenylisoquinoline)iridium(III) (Ir(piq)3), bis (2-benzo[b]thiophene-2-yl-pyridine) (acetylacetonate)iridium(III) (Ir(btp)₂(acac)), tris(dibenzoylmethane) phenanthrene europium(III)(Eu(dbm)3(phen)), tris[4,4′-di-tert-butyl-(2,2′)-bipyridine]ruthenium(III)complex(Ru(dtbbpy)3*2(PF₆)), [4-(dicyano-methylene)-2-methyl-6-(p-dimethylaminostyryl)-4H-pyrane](DCM1), [2-methyl-6-[2-(2,3,6,7-tetrahydro-1H,5H-benzoquinolizin-9-yl)-ethenyl]-4H-pyran-4-ylidene]propane-dinitrile] (DCM2), Eu(thenoyltrifluoroacetone)3 (Eu(TTA)3, 4-(Dicyanomethylene)-2-tert-butyl-6-(1,1,7,7-tetramethyljulolidin-4-yl-vinyl)-4H-pyran (DCJTB), fluoro resin, vinyl resin, or etc.

In some embodiments, the second organic light emitting layer 162 may be disposed in a second sub-pixel area SP2. In some embodiments, the second organic light emitting layer 162 may emit green visible rays and may include 3-(2-benzotiazoyl)-7-(diethylamino) (Coumarin 6) 2,3,6,7-tetrahydro-1,1,7,7,-tetramethyl-1H,5H,11H-10-(2benzotiazoyl)quinolizino-[9,9a,1gh]coumarin (C545T), N,N′-dimethylquinacridone (DMQA), tris(2-phenylprydine)iridium(III) (Ir(ppy)3), fluoro resin, vinyl resin, or etc.

In some embodiments, the third organic light emitting layer 163 may be disposed in a third sub-pixel area SP3. In some embodiments, the third organic light emitting layer 163 may emit blue visible rays and may include oxadiazole dimmer dye (Bis-DAPDXP), spiro-4,4′-bis(2,2′diphenylvinil)-1,1′-biphenyl (spiro-DPVBi), 2,2′,7,7′-tetrakis(biphenyl-4-yl)-9,9′-spirobifluorene (spiro-6P), triarylamine compound, bis(styryl)amine, 4,4′-bis(9-ethyl-3-carbazovinylene)-1,1′-biphenyl (BCzVBi), perylene, 2,5,8,11-tetra-tert-butylperylene (TPBe), 9H-carbazole-3,3′-(1,4-phenylene-di-2,1-ethene-diyl)bis[9-ethyl-(9C)] (BCzVB), 4,4-bis[4-(di-p-toylamino)styryl]biphenyl (DPAVBi), 4-(di-p-toylamino)-4′-[(di-p-toylamino)styryl]stillbene (DPAVB), 4,4′-bis[4-(diphenylamino)styryl]biphenyl (BDAVBi), bis(3,5-difluoro-2-(2-pyridyl)phenyl-(2-carboxypyridyl)iridium III (FIrPic), polyfluorene polymer, polybinyl polymer, or etc.

In some embodiments, the electron transfer layer 170 may be disposed on the organic light emitting layer 160. In some embodiments, the electron transfer layer 170 may include 4,7-diphenyl-1,10-phenanthroline (Bphen), (Bis(2-methyl-8-quinolinolate)-4-(phenylphenolato)aluminium (BAlq), (tris(8-quinolate) aluminium (Alq3), (beryllium bis(benzoquinolin-10-olate) (Bebq2), (2,2′,2″-(1,3,5-Benzinetriyl)-tris(1-phenyl-1-Hbenzimidazole)) (TPBi), or etc. In some embodiments, the electron transfer layer 170 serves to easily move electrons from an electron injection layer to the organic light emitting layer 160.

In some embodiments, the electron injection layer (not illustrated) may be disposed on the electron transfer layer 170. In some embodiments, the electron injection layer may include PBD, PF-6P, PyPySPyPy, LiF, NaCl, CaF, Li₂O, BaO, Liq, or etc. In some embodiments, the electron injection layer serves to easily move electrons from the second electrode 180 to the electron transfer layer 170.

In some embodiments, the hole injection layer 120, the hole transfer layer 140, the electron transfer layer 170 and the electron transfer layer may improve electrical characteristics so that power consumption, lifetime and luminance of organic light emitting diode may be improved.

In another embodiment, one or more of the hole injection layer 120, the hole transfer layer 140, the electron transfer layer 170 and the electron transfer layer may be omitted as desired.

In some embodiments, the second electrode 180 may be disposed on the organic light emitting layer 180. In some embodiments, the second electrode 180 may be a reflection electrode or a transmission electrode depending on an emitting type of the organic light emitting display device. When the first electrode 110 is a transmission electrode, the second electrode may be a reflection electrode and, may include aluminum (Al), silver (Ag), gold (Au), platinum (Pt), chromium (Cr), tungsten (W), molybdenum (Mo), titanium (Ti) or palladium (Pd), or etc. When the first electrode 110 is a reflection electrode, the second electrode may be a transmission electrode, and may include indium zinc oxide (IZO), indium tin oxide (ITO), gallium zinc oxide (GZO), zinc oxide(ZnOx), gallium oxide(GaOx), tin oxide(TiOx) or indium oxide(InOx), or etc.

FIG. 2 is a cross-sectional view illustrating an organic light emitting display device according to an exemplary embodiment.

Referring to FIG. 2, an organic light emitting display device 20 includes a base substrate 100, a first electrode 110, a hole injection layer 120, an interlayer 125, a functional layer 130, a hole transfer layer 140, an optical control layer 150, an electron transfer layer 170 and a second electrode 180.

In some embodiments, the organic light emitting display device 20 is substantially same as the organic light emitting display device 10 illustrated in FIG. 1 except for the interlayer 125. Thus, repeated description will be omitted.

In some embodiments, the interlayer 125 may be disposed between the hole injection layer 120 and the functional layer 130. In some embodiments, the interlayer 125 may be formed from materials same as the hole injection layer 120 and the hole transfer layer 140.

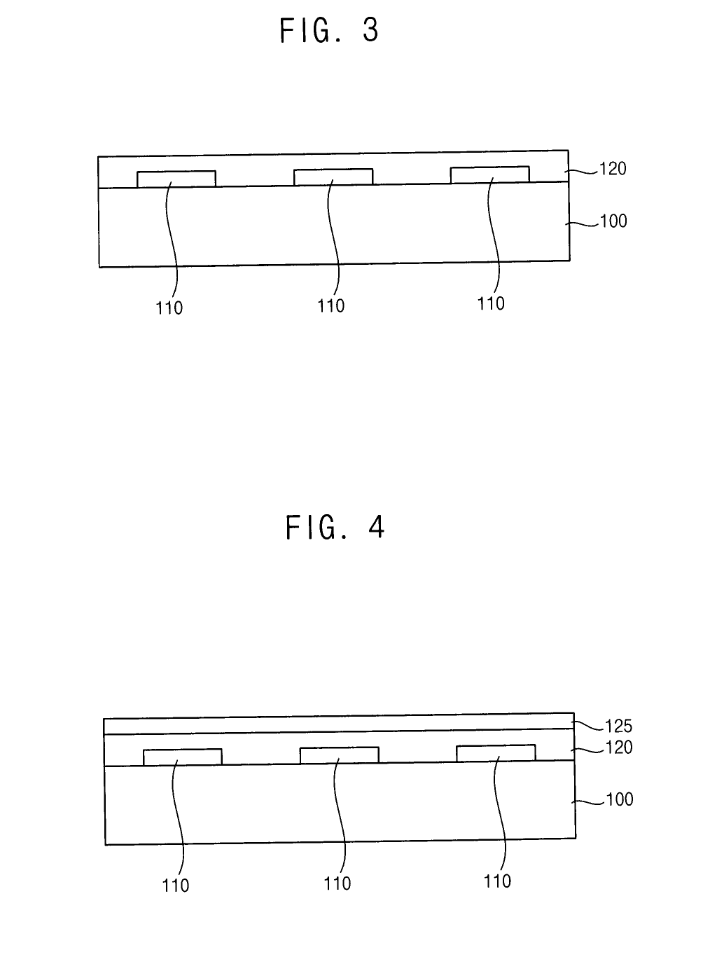

FIGS. 3 to 10 are cross-sectional views illustrating a method of manufacturing an organic light emitting display device illustrated in FIG. 2.

Referring to FIG. 3, the hole injection layer 120 may be formed on the first electrode 110. In some embodiments, materials such as phthalocyanine compound, TCTA, m-MTDATA, m-MTDAPB, or etc may be used for a deposition process of the hole injection layer 120. Processes such as mask deposition, photolithopraphy process, printing process, inkjet process, or etc may be used for the deposition process of the hole injection layer 120. In some embodiments, the deposition process may include sputtering process, chemical vapor deposition process, pulsed laser deposition process, vacuum deposition process, atomic layer deposition process, or etc. When the hole injection layer 120 is formed by mask deposition process, a mask exposing the first electrode 110 is arranged on the substrate having the first electrode 110, deposition materials are provided through an opening of the mask by using a heating, a sputtering, or etc. to be directly deposited on the first electrode 110.

FIG. 4 is a cross-sectional view illustrating a method of manufacturing an interlayer illustrated in FIG. 3.

Referring to FIG. 4, the interlayer 125 is formed on the hole injection layer 120. In some embodiments, the interlayer 125 may be formed from materials same as the hole injection layer 120 and the hole transfer layer 140. In an exemplary embodiment, materials such as phthalocyanine compound, TCTA, m-MTDATA, m-MTDAPB, or etc may be used for the deposition process of the interlayer 125. Processes such as vapor deposition process, mask deposition process, photolithopraphy process, printing process, inkjet process, or etc may be used for the deposition process of the interlayer 125. In some embodiments, the vapor deposition process may include sputtering process, chemical vapor deposition process, pulsed laser deposition process, vacuum deposition process, atomic layer deposition process, or etc. In some embodiments, the interlayer 125 may be formed by mask deposition process.

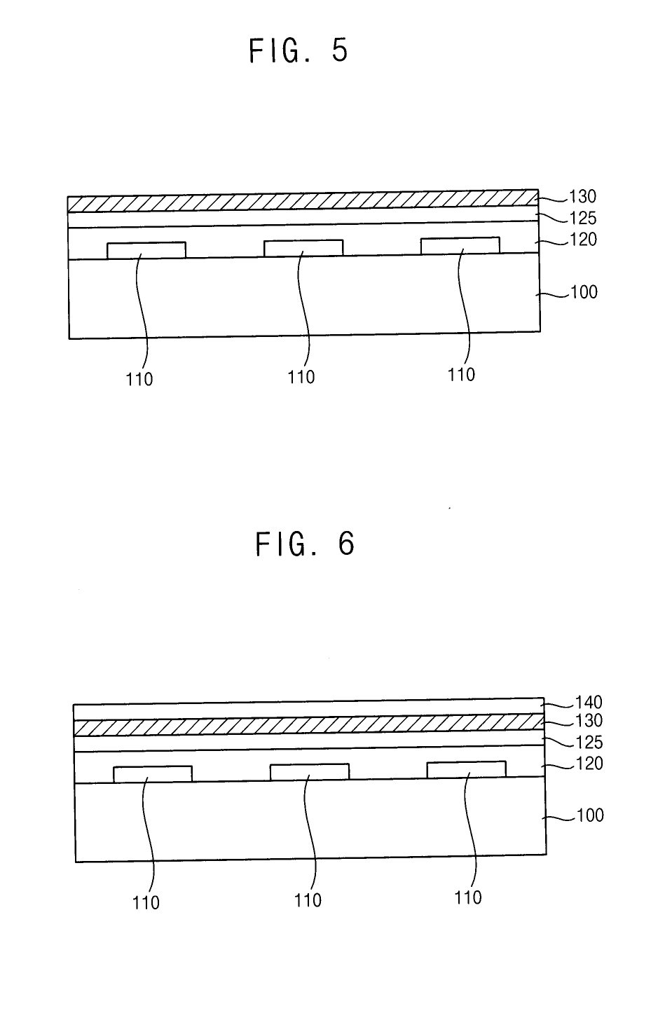

FIG. 5 is a cross-sectional view illustrating a method of manufacturing a functional layer 130 illustrated in FIG. 4.

Referring to FIG. 5, the functional layer 130 is formed on the interlayer 125. In some embodiments, the functional layer 130 may be being doped with a host material and a dopant material. In some embodiments, the functional layer 130 may include blue host materials such as Alq3, (4,4′-N,N′-dicabazolebiphenyl), poly(n-vinylcabazole) (CBP), (9,10-di(naphthalene-2-yl)anthracene) (ADN), TCTA, 1,3,5-tris(Nphenylbenzimidazole-2-yl)benzene (TPBI), 3-tert-butyl-9,10-di(naphth-2-yl) anthracene (TBADN), distyrylarylene (DSA), anthracene dinaphthalene, anthracene dibiphenyl, anthracene naphthalene biphenyl or anthracene diphenyl. In some embodiments, the functional layer 130 may include blue dopant materials such as oxadiazole dimmer dye (Bis-DAPDXP), spiro-4,4′-bis(2,2′diphenylvinil)-1,1′-biphenyl (spiro-DPVBi), 2,2′,7,7′-tetrakis(biphenyl-4-yl)-9,9′-spirobifluorene (spiro-6P), triarylamine compound, bis(styryl)amine, 4,4′-bis(9-ethyl-3-carbazovinylene)-1,1′-biphenyl (BCzVBi), perylene, 2,5,8,11-tetra-tert-butylperylene (TPBe), 9H-carbazole-3,3′-(1,4-phenylene-di-2,1-ethene-diyl)bis[9-ethyl-(9C)] (BCzVB), 4,4-bis[4-(di-p-toylamino)styryl]biphenyl (DPAVBi), 4-(di-p-toylamino)-4′-[(di-p-toylamino)styryl]stillbene (DPAVB), 4,4′-bis[4-(diphenylamino)styryl]biphenyl (BDAVBi), bis(3,5-difluoro-2-(2-pyridyl)phenyl-(2-carboxypyridyl)iridium III (FIrPic), polyfluorene polymer or polybinyl polymer.

FIG. 6 is a cross-sectional view illustrating a method of manufacturing a hole transfer layer 140 illustrated in FIG. 5.

Referring to FIG. 6, the transfer layer 140 is formed on the functional layer 130.

In some embodiments, materials such as N,N-bis(3-methylphenyl)-N,N′-diphenyl-[1,1-biphenyl]-4,4′-diamine (TPC), N,N′-di(naphthalene-1-yl)-N,N′-diphenyl benzidine (α-NPD), or etc may be included in the hole transfer layer 140. Processes such as vapor deposition process, mask deposition process, photolithopraphy process, printing process, inkjet process, or etc may be used for the deposition process of the hole transfer layer 140. In some embodiments, the vapor deposition process may include sputtering process, chemical vapor deposition process, pulsed laser deposition process, vacuum deposition process, atomic layer deposition process, or etc. In some embodiments, the hole transfer layer 140 may be formed by mask deposition process.

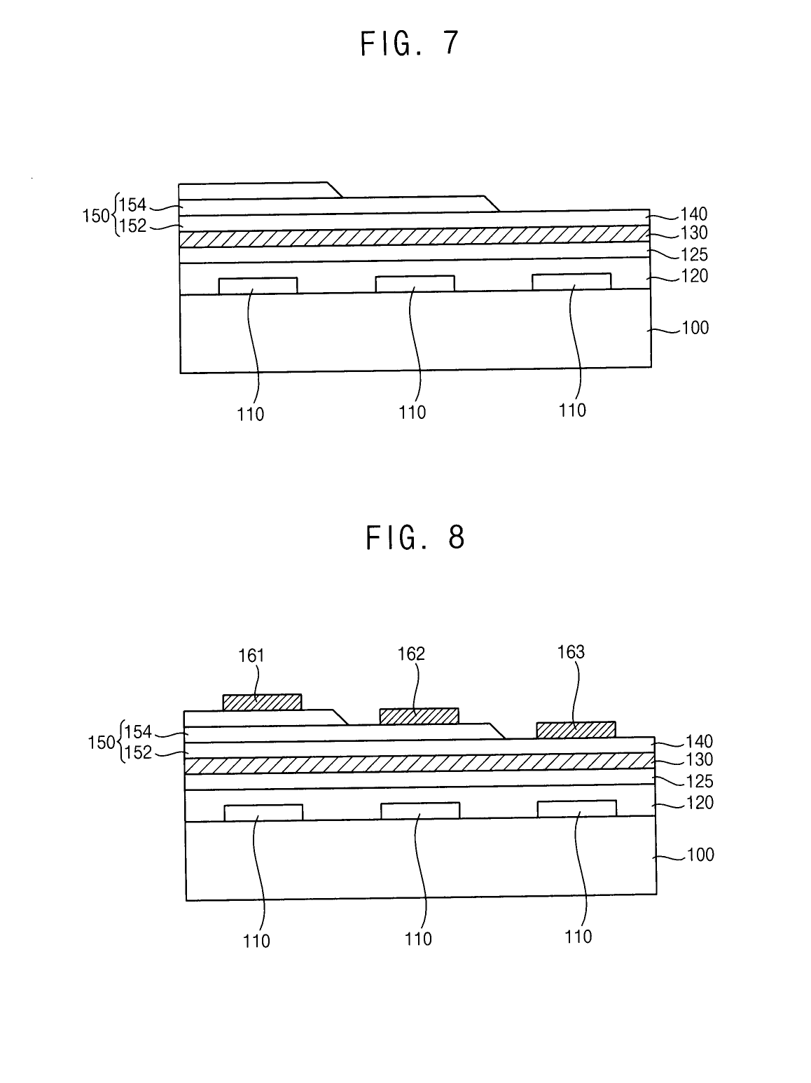

FIG. 7 is a cross-sectional view illustrating a method of manufacturing an optical control layer 150 illustrated in FIG. 5.

Referring to FIG. 7, the optical control layer 150 may be formed on the hole transfer layer 140. In some embodiments, the optical control layer 150 includes the first optical path control layer 152 and the second optical path control layer 154. In some embodiments, the optical control layer 150 serves as a layer for resonance of light from the organic light emitting layer 160. In some embodiments, the optical control layer 150 may be formed from hole transfer materials, and may have different thicknesses to have a resonance thickness corresponding to sub-pixels. In some embodiments, a thickness of the hole transfer layer 140 for the blue sub-pixel may be adjusted so that the optical control layer 150 may be omitted for the blue sub-pixel. In some embodiments, the second optical path control layer 154 may be disposed on the first optical path control layer 152. In some embodiments, the first optical path control layer 152 and the second optical path control layer 154 may include alloy or metals which have high reflectance such as Ag or Mg and a material such as SiN, SiO, TiO₂, Ta₂O₅, ITO, IZO, or etc. for controlling optical path.

FIG. 8 is a cross-sectional view illustrating a method of manufacturing an organic light emitting layer 160 illustrated in FIG. 7.

Referring to FIG. 8, the organic light emitting layer 160 is formed on the optical control layer 150. In some embodiments, the first organic light emitting layer 161, the second organic light emitting layer 162 and the third organic light emitting layer 163 may be formed from the organic light emitting layer 160. In some embodiments, red light emitting materials may be used for the deposition process of the first organic light emitting 161. Processes such as vapor deposition process, mask deposition process, photolithopraphy process, printing process, inkjet process, or etc may be used for the deposition process of the first organic light emitting 161. In some embodiments, the vapor deposition process may include sputtering process, chemical vapor deposition process, pulsed laser deposition process, vacuum deposition process, atomic layer deposition process, or etc. In some embodiments, the first organic light emitting 161 may be formed by mask deposition process. In some embodiments, the first organic light emitting 161 may be formed from different materials each other.

In some embodiments, green light emitting materials may be used for the deposition process of the second organic light emitting 162. Processes such as vapor deposition process, mask deposition process, photolithopraphy process, printing process, inkjet process, or etc may be used for the deposition process of the second organic light emitting 162. In some embodiments, the vapor deposition process may include sputtering process, chemical vapor deposition process, pulsed laser deposition process, vacuum deposition process, atomic layer deposition process, or etc. In some embodiments, the second organic light emitting 162 may be formed by mask deposition process. In some embodiments, the second organic light emitting 162 may be formed from different materials each other.

In some embodiments, green light emitting materials may be used for the deposition process of the third organic light emitting 163. Processes such as vapor deposition process, mask deposition process, photolithopraphy process, printing process, inkjet process, or etc may be used for the deposition process of the third organic light emitting 163. In some embodiments, the vapor deposition process may include sputtering process, chemical vapor deposition process, pulsed laser deposition process, vacuum deposition process, atomic layer deposition process, or etc. In some embodiments, the third organic light emitting 163 may be formed by mask deposition process. In some embodiments, the third organic light emitting 163 may be formed from different materials each other.

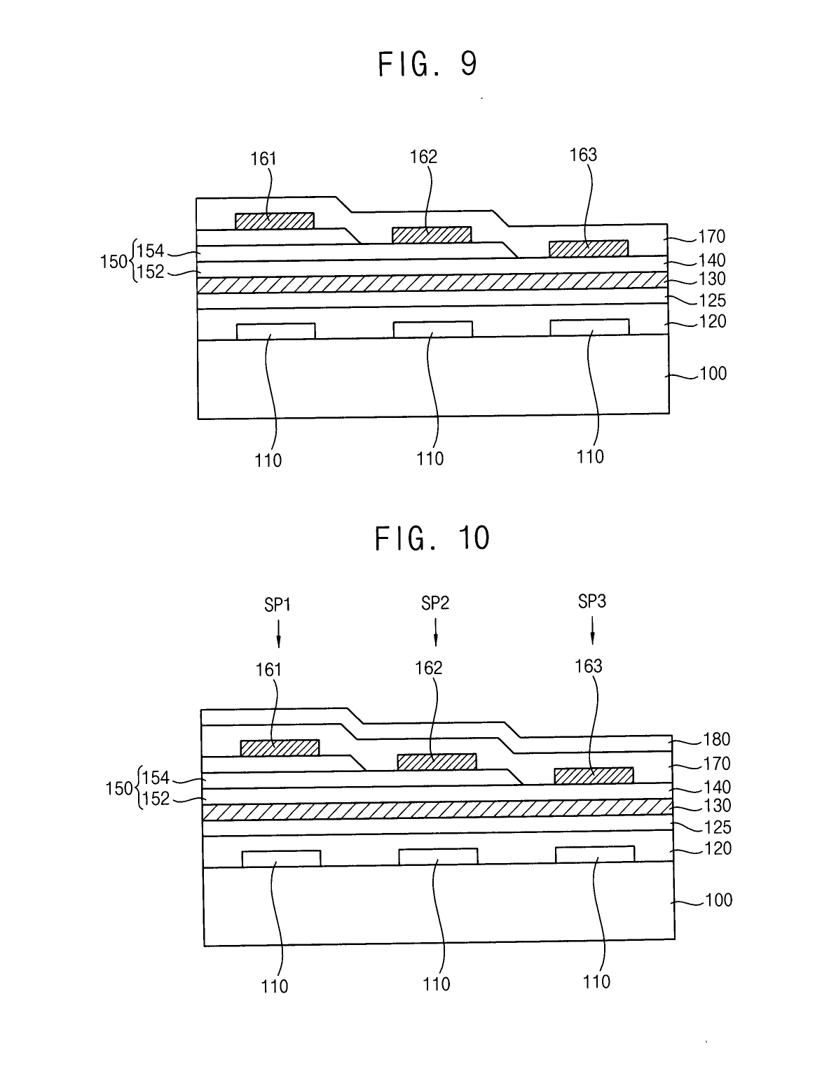

FIG. 9 is a cross-sectional view illustrating a method of manufacturing an electron transfer layer 170 illustrated in FIG. 8.

Referring to FIG. 9, the electron transfer layer 170 may be formed on the organic light emitting layer 160. In some embodiments, Processes such as vapor deposition process, mask deposition process, photolithopraphy process, printing process, inkjet process, or etc may be used for the deposition process of the electron transfer layer 170. In some embodiments, the vapor deposition process may include sputtering process, chemical vapor deposition process, pulsed laser deposition process, vacuum deposition process, atomic layer deposition process, or etc. In an exemplary embodiment, the electron transfer layer 170 may be formed by mask deposition process.

In some embodiments, a method of manufacturing the electron injection layer may be further described (not illustrated). In an exemplary embodiment, materials such as PBD, PF-6P, PyPySPyPy, LiF, NaCl, CaF, Li₂O, BaO, Liq, or etc may be used for the deposition process of the electron injection layer. Processes such as vapor deposition process, mask deposition process, photolithopraphy process, printing process, inkjet process, or etc may be used for the deposition process of the electron injection layer. In some embodiments, the vapor deposition process may include sputtering process, chemical vapor deposition process, pulsed laser deposition process, vacuum deposition process, atomic layer deposition process, or etc. In some embodiments, the electron injection layer may be formed by mask deposition process.

FIG. 10 is a cross-sectional view illustrating a method of manufacturing a second electrode 180 illustrated in FIG. 9.

Referring to FIG. 10, the second electrode 180 including conductive materials is formed on the electron transfer layer 170. Conductive materials may be used for the deposition process of the second electrode 180. Processes such as vapor deposition process, mask deposition process, photolithopraphy process, printing process, inkjet process, or etc may be used for the deposition process of the second electrode 180. In some embodiments, the vapor deposition process may include sputtering process, chemical vapor deposition process, pulsed laser deposition process, vacuum deposition process, atomic layer deposition process, or etc. In some embodiments, the organic light emitting display device is a top emission type, the first electrode 110 includes materials which have high reflectance, and the second electrode 180 includes transparent materials. In some embodiments, an organic light emitting display devices may be bottom emission type having a first electrode including transparent materials, and a second electrode including materials which have high reflectance.

In some embodiments, the functional layer 130 including blue light emitting materials may be disposed between the hole transfer layer 120 and the hole injection layer 140. Thus, lifetime and luminous efficiency of an organic light emitting diode may be improved, and roll-off may be improved in red diode including phosphors.

### Examples

TABLE 1 represents driving voltage, current efficiency and color coordinate of organic light emitting diodes according to Examples and Comparative Examples. Comparative Example 1 represents a general blue reference diode including a hole transfer layer, a hole injection layer and an interlayer between the hole transfer layer and the hole injection layer. Example 1 represents a diode including a functional layer of 1 Å including a host material and a dopant material, and disposed between a hole transfer and a interlayer. Example 2 represents a diode including a functional layer of 10 Å including a host material and a dopant material, and disposed between a hole transfer and an interlayer. Example 3 represents a diode including a functional layer of 10 Å including only a host material, and disposed between a hole transfer layer and an interlayer. Example 4 represents a diode including a functional layer of 10 Å including only a dopant material, and disposed between a hole transfer layer and an interlayer. The diodes were driven to emit a light of 350 nit. 9,10-di(2-naphthyl)anthracene (ADN) was used as a host material, and Ir(pFCNp)3 was used as a dopant material.

TABLE 1

| | Driving voltage | Current | X color | Y color |
|---|---|---|---|---|
| Category | variation(V) | efficiency(Cd/A) | coordinate | coordinate |
| Comparative | 3.86 | 3.73 | 0.143 | 0.076 |
| Example 1 | | | | |
| Example 1 | 3.74 | 3.78 | 0.143 | 0.077 |
| Example 2 | 4.5 | 4.01 | 0.143 | 0.075 |
| Example 3 | 4.45 | 3.86 | 0.143 | 0.080 |
| Example 4 | 3.76 | 3.83 | 0.143 | 0.077 |

Referring TABLE 1, Example 1 is increased by about 0.05 Cd/A than comparative embodiment 1. Example 2 is increased by about 0.64V than Comparative Example 1. Thus, it can be noted that the functional layer including a host material and a dopant material may improve current efficiency of an organic light emitting diode.

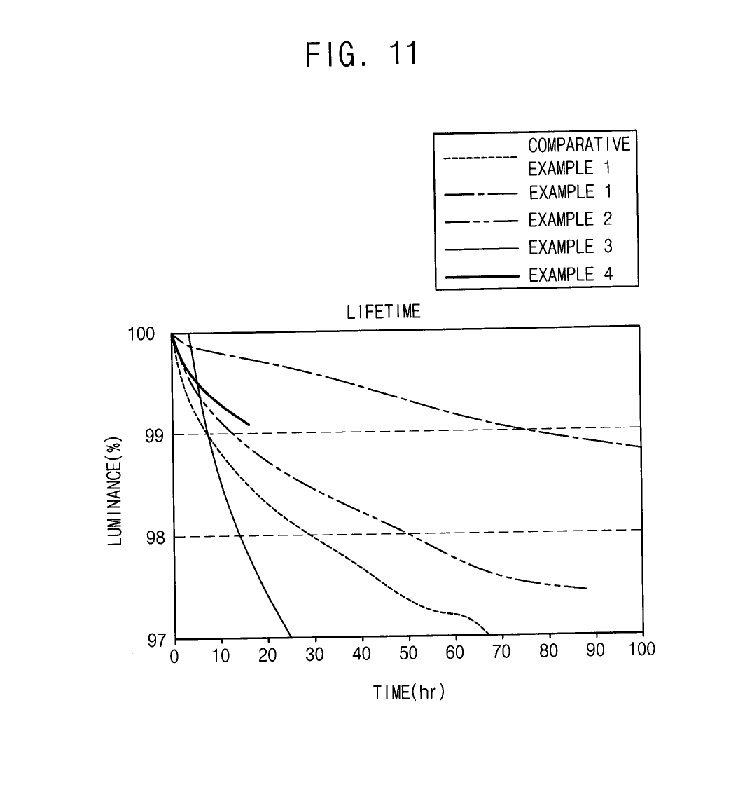

FIG. 11 is a graph illustrating life time of an organic light emitting display device according to an Examples 1-4 in comparison to Comparative Example 1.

Referring to FIG. 11, X axis represents lifetime (hr) and Y axis represents luminance(%). When comparing the slopes of Comparative Example 1 and Examples 1 to 4 with each other, it can be noted that lifetime of Example 1 is longer than the lifetime of Comparative Example 1.

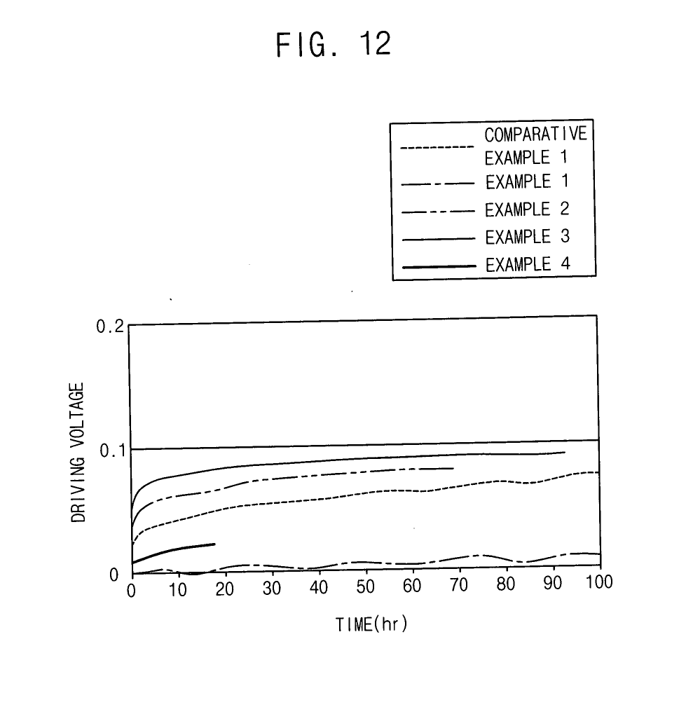

FIG. 12 is a graph illustrating progressive driving voltage of an organic light emitting display device according to Comparative Example 1 and Examples 1 to 4.

Referring to FIG. 12, X axis represents time (hr) and Y axis represents progressive driving voltage. When comparing the slopes of Comparative Example 1, Examples 1 to 4, driving voltage of Example 2 is higher driving voltage than Comparative Example 1. Thus, current efficiency and lifetime of an organic light emitting diode may be improved to include the functional layer including a host material and a dopant material.

In some embodiments, the organic light emitting display device may include the functional layer including a host material and a dopant material between the hole injection layer and the interlayer as disclosed and described herein. Thus, electrical characteristic, lifetime and efficiency of an organic light emitting display device may be improved.

In the present disclosure, the terms “Example” and “Comparative Example” are used arbitrarily to simply identify a particular example or experimentation and should not be interpreted as admission of prior art. The foregoing is illustrative of the embodiments and is not to be construed as limiting thereof. Although exemplary embodiments of the disclosure have been described, those skilled in the art will readily appreciate that many modifications are possible without materially departing from the novel teachings and advantages of the embodiments. Accordingly, all such modifications are intended to be included within the scope of the invention as defined in the claims. In the claims, means-plus-function clauses are intended to cover the structures described herein as performing the recited function and not only structural equivalents but also equivalent structures. While the present embodiments have been particularly shown and described with reference to exemplary embodiments thereof, it will be understood by those of ordinary skill in the art that various changes in form and details may be made therein without departing from the spirit and scope of the present embodiments as defined by the following claims.

What is claimed is:

1. An organic light emitting display device comprising:
a first electrode;
a second electrode disposed on the first electrode;
an organic light emitting layer disposed on the first electrode;
a hole transfer layer disposed between the first electrode and the organic light emitting layer;
a hole injection layer disposed between the first electrode and the hole transfer layer; and
a functional layer disposed between the hole transfer layer and the hole injection layer, and comprising a blue light emitting material.

2. The organic light emitting display device of claim 1, further comprising an interlayer disposed between the hole transfer layer and the hole injection layer.

3. The organic light emitting display device of claim 1, further comprising an electron injection layer disposed between the organic light emitting layer and the second electrode.

4. The organic light emitting display device of claim 3, further comprising an electron transfer layer disposed between the electron injection layer and the organic light emitting layer.

5. The organic light emitting display device of claim 1, further comprising an optical control layer disposed between the organic light emitting layer and the functional layer.

6. The organic light emitting display device of claim 1, wherein the organic light emitting layer comprises a first organic light emitting layer, a second organic light emitting layer and a third organic light emitting layer, and the first emitting layer emits blue visible ray, the second emitting layer emits red visible ray and the third emitting layer emits green visible ray.

7. The organic light emitting display device of claim 1, wherein the first organic light emitting layer is disposed in a first sub-pixel area, the second organic light emitting layer is disposed in a second sub-pixel area, and the third organic light emitting layer is disposed in a third sub-pixel area.

8. The organic light emitting display device of claim 1, wherein the blue light emitting material comprises at least one selected from the group consisting of Alq3, 4,4′-N,N′-dicabazolebiphenyl (CBP), poly(n-vinylcabazole), 9,10-di(naphthalene-2-yl)anthracene (ADN), Tris(4-carbazoyl-9-ylphenyl)amine (TCTA), 1,3,5-tris(Nphenylbenzimidazole-2-yl)benzene (TPBI), 3-tert-butyl-9,10-di(naphth-2-yl (TBADN) anthracene), distyrylarylene (DSA), anthracene dinaphthalene, anthracene dibiphenyl, anthracene naphthalene biphenyl and anthracene diphenyl.

9. The organic light emitting display device of claim 1, wherein the functional layer comprises at least one selected from the group consisting of oxadiazole dimmer dye (Bis-DAPDXP), spiro-4,4′-bis(2,2′diphenylvinil)-1,1′-biphenyl (spiro-DPVBi), 2,2′,7,7′-tetrakis(biphenyl-4-yl)-9,9′-spirobifluorene (spiro-6P), triarylamine compound, bis(styryl)amine, 4,4′-bis(9-ethyl-3-carbazovinylene)-1,1′-biphenyl (BCzVBi), perylene, 2,5,8,11-tetra-tert-butylperylene (TPBe), 9H-carbazole-3,3′-(1,4-phenylene-di-2,1-ethene-diyl)bis[9-ethyl-(9C)] (BCzVB), 4,4-bis[4-(di-p-toylamino)styryl]biphenyl (DPAVBi), 4-(di-p-toylamino)-4′-[(di-p-toylamino)styryl]stillbene (DPAVB), 4,4′-bis[4-(diphenylamino)styryl]biphenyl (BDAVBi), bis(3,5-difluoro-2-(2-pyridyl)phenyl-(2-carboxypyridyl)iridium III (FIrPic), polyfluorene polymer and polybinyl polymer.

10. The organic light emitting display device of claim 1, wherein a thickness of the functional layer is about 1 Å to about 50 Å.

11. A method of manufacturing an organic light emitting display device, the method comprising:
forming a first electrode on a base substrate;
forming a hole injection layer;
forming a functional layer comprising a blue light emitting material;
forming a hole transfer layer;
forming an organic light emitting layer comprising a first organic light emitting layer, a second organic layer and a third organic layer disposed on the first electrode; and
forming a second electrode disposed on the first electrode.

12. The method of claim 11, further comprising:
forming an interlayer disposed between the hole transfer layer and the hole injection layer.

13. The method of claim 11, further comprising:
forming an electron injection layer disposed between the first electrode and the second electrode.

14. The method of claim 13, further comprising:
forming an electron transfer layer disposed between the electron injection layer and the organic light emitting layer.

15. The method of claim 11, further comprising:
forming an optical control layer disposed between the organic light emitting layer and the functional layer.

16. The method of claim 11, wherein the functional layer comprises at least one selected from the group consisting of Alq3, 4,4′-N,N′-dicabazolebiphenyl (CBP), poly(n-vinylcabazole), 9,10-di(naphthalene-2-yl)anthracene (ADN), Tris(4-carbazoyl-9-ylphenyl)amine (TCTA), 1,3,5-tris(Nphenylbenzimidazole-2-yl)benzene (TPBI), 3-tert-butyl-9,10-di(naphth-2-yl) anthracene (TBADN), distyrylarylene (DSA), anthracene dinaphthalene, anthracene dibiphenyl, anthracene naphthalene biphenyl and anthracene diphenyl.

17. The method of claim 11, wherein the functional layer comprises at least one selected from the group consisting of oxadiazole dimmer dye (Bis-DAPDXP), spiro-4,4′-bis(2,2′diphenylvinil)-1,1′-biphenyl (spiro-DPVBi), 2,2′,7,7′-tetrakis(biphenyl-4-yl)-9,9′-spirobifluorene (spiro-6P), triarylamine compound, bis(styryl)amine, 4,4′-bis(9-ethyl-3-carbazovinylene)-1,1′-biphenyl (BCzVBi), perylene, 2,5,8,11-tetra-tert-butylperylene (TPBe), 9H-carbazole-3,3′-(1,4-phenylene-di-2,1-ethene-diyl)bis[9-ethyl-(9C)] (BCzVB), 4,4-bis[4-(di-p-toylamino)styryl]biphenyl (DPAVBi), 4-(di-p-toylamino)-4′-[(di-p-toylamino)styryl]stillbene (DPAVB), 4,4′-bis[4-(diphenylamino)styryl]biphenyl (BDAVBi), bis(3,5-difluoro-2-(2-pyridyl)phenyl-(2-carboxypyridyl)iridium III (FIrPic), polyfluorene polymer and polybinyl polymer.
